(19) United States
(12) Patent Application Publication
(10) Pub. No.: US 2012/0032191 A1
(43) Pub. Date: Feb. 9, 2012

(54) METHOD FOR MANUFACTURING SILICON CARBIDE SUBSTRATE AND SILICON CARBIDE SUBSTRATE

(75) Inventors: Shin Harada, Osaka (JP); Makoto Sasaki, Hyogo (JP); Taro Nishiguchi, Hyogo (JP); Hideto Tamaso, Osaka (JP); Yasuo Namikawa, Osaka (JP)

(73) Assignee: SUMITOMO ELECTRIC INDUSTRIES, LTD., Osaka-shi (JP)

(21) Appl. No.: 13/259,012

(22) PCT Filed: Sep. 27, 2010
(86) PCT No.: PCT/JP2010/066703

§ 371 Date: Sep. 22, 2011

(30) Foreign Application Priority Data
Oct. 30, 2009 (JP) 2009-250478

(51) Int. Cl. H01L 29/24; H01L 21/20

(52) U.S. Cl. 257/77; 438/478; 257/E29.104; 257/E21.09

(57) ABSTRACT

A method for manufacturing a silicon carbide substrate (1) having a large diameter provided readily includes the steps of: preparing a plurality of SiC substrates (20) each made of single-crystal silicon carbide; and connecting end surfaces (20B) of the plurality of SiC substrates (20) to one another such that the plurality of SiC substrates (20) are arranged side by side when viewed in a planar view.

### TECHNICAL FIELD

The present invention relates to a method for manufacturing a silicon carbide substrate, and the silicon carbide substrate, more particularly, a method for manufacturing a silicon carbide substrate that can be readily provided with a large diameter, and such a silicon carbide substrate.

### BACKGROUND ART

In recent years, in order to achieve high reverse breakdown voltage, low loss, and utilization of semiconductor devices under a high temperature environment, silicon carbide (SiC) has begun to be adopted as a material for a semiconductor device. Silicon carbide is a wide band gap semiconductor having a band gap larger than that of silicon, which has been conventionally widely used as a material for semiconductor devices. Hence, by adopting silicon carbide as a material for a semiconductor device, the semiconductor device can have a high reverse breakdown voltage, reduced on-resistance, and the like. Further, the semiconductor device thus adopting silicon carbide as its material has characteristics less deteriorated even under a high temperature environment than those of a semiconductor device adopting silicon as its material, advantageously.

In order to efficiently manufacture such semiconductor devices, it is effective to use a substrate having a large diameter. Accordingly, various studies have been conducted on silicon carbide substrates made of single-crystal silicon carbide and having a diameter of 3 inches or 4 inches as well as methods for manufacturing such silicon carbide substrates. For example, methods for manufacturing such silicon carbide substrates using a sublimation method have been proposed (for example, see US Patent Application Publication No. 2006/0073707 (Patent Literature 1), US Patent Application Publication No. 2007/0209577 (Patent Literature 2), and US Patent Application Publication No. 2006/0075958 (Patent Literature 3)).

### CITATION LIST

### Patent Literature

PTL 1: US Patent Application Publication No. 2006/0073707

PTL 2: US Patent Application Publication No. 2007/0209577

PTL 3: US Patent Application Publication No. 2006/0075958

### SUMMARY OF INVENTION

### Technical Problem

In order to manufacture semiconductor devices more efficiently, it is required to provide a silicon carbide substrate with a larger diameter (4 inches or greater). Here, in order to fabricate a silicon carbide substrate having a large diameter using the sublimation method, temperature needs to be uniform in a wide area thereof. However, because the growth temperature of silicon carbide in the sublimation method is high, specifically, not less than 2000° C., it is difficult to control the temperature. Hence, it is not easy to have a wide area in which temperature is uniform. In addition, it is also difficult to achieve sufficient reproducibility for temperature distribution. Further, in fabricating a silicon carbide substrate using the sublimation method, it is difficult to check a process of crystal growth of silicon carbide. Even when the crystal growth of silicon carbide is done under seemingly the same conditions, substrates (crystals) obtained may differ in quality, disadvantageously. Accordingly, even when the sublimation method, which relatively readily allows for a large diameter, is used, it is not easy to fabricate a silicon carbide substrate excellent in crystallinity and having a large diameter (for example, 4 inches or greater), disadvantageously.

In view of these, an object of the present invention is to provide a method for manufacturing a silicon carbide substrate excellent in crystallinity and having a large diameter, as well as such a silicon carbide substrate.

### Solution to Problem

A method for manufacturing a silicon carbide substrate in the present invention includes the steps of: preparing a plurality of SiC substrates each made of single-crystal silicon carbide; and connecting end surfaces of the plurality of SiC substrates to one another such that the plurality of SiC substrates are arranged side by side when viewed in a planar view.

In the method for manufacturing the silicon carbide substrate in the present invention, the end surfaces of the SiC substrates are connected to one another such that the plurality of SiC substrates each made of single-crystal silicon carbide are arranged side by side when viewed in a planar view. As described above, it is difficult for a substrate made of single-crystal silicon carbide to keep its high quality and have a large diameter. To address this, a plurality of high-quality SiC substrates each having a small diameter and obtained from a silicon carbide single crystal are arranged side by side when viewed in a planar view and their end surfaces are connected to one another, thereby obtaining a silicon carbide substrate that is excellent in crystallinity and can be handled as a silicon carbide substrate having a large diameter.

Thus, according to the method for manufacturing the silicon carbide substrate in the present invention, a silicon carbide substrate excellent in crystallinity and having a large diameter can be manufactured. It should be noted that in order to attain efficient process of manufacturing semiconductor devices using the silicon carbide substrate, the plurality of SiC substrates are preferably arranged in the form of a matrix when viewed in a planar view. Further, in the silicon carbide substrate of the present invention, the end surfaces of the SiC layers may be directly connected to one another, or may be connected to one another with intermediate layers interposed therebetween. As each of the intermediate layers, it is preferable to employ a semiconductor or a conductor. Specifically, examples of the intermediate layer usable include: an intermediate layer formed by sintering a carbon-containing adhesive agent and electrically conductive due to the carbon contained therein; an intermediate layer made of a metal and accordingly electrically conductive; and an intermediate layer made of silicon carbide. In the case where the intermediate layer made of a metal is employed, the metal is preferably capable of making ohmic contact with silicon carbide by forming a silicide.

The method for manufacturing the silicon carbide substrate may further include the step of forming a filling portion for filling a gap between the plurality of SiC substrates.

The surface of the silicon carbide substrate is usually smoothed by polishing or the like and then is used for manufacturing of semiconductor devices. However, when the plurality of SiC substrates are arranged side by side when viewed in a planar view, it is difficult to bring the SiC substrates into intimate contact with one another completely, with the result that gaps are formed between the SiC substrates. When such a surface of the silicon carbide substrate is polished, foreign matters such as abrasive particles come into the gaps. The foreign matters may not be completely removed even by a subsequent cleaning process. Further, the foreign matters thus remaining in the gaps between the SiC substrates may have an adverse effect over the manufacturing of semiconductor devices using the silicon carbide substrate. To address this, the step of forming the filling portion is performed, thereby restraining the adverse effect that would be caused by the foreign matters.

It should be noted that the filling portion may be made of, for example, silicon carbide or silicon dioxide. A filling portion made of silicon carbide can be formed using, for example, a CVD (Chemical Vapor Deposition) epitaxial method, a sublimation method, a liquid phase epitaxy employing a Si melt, or the like. The liquid phase epitaxy employing the Si melt is implemented by, for example, bringing the SiC substrates into contact with the Si melt retained in a carbon crucible to supply the gaps between the SiC substrates with Si from the melt and carbon from the crucible. On the other hand, a filling portion made of silicon dioxide can be formed using, for example, the CVD method.

In the method for manufacturing the silicon carbide substrate, in the step of forming the filling portion, the filling portion formed may have an impurity concentration greater than 5×10¹⁸ cm⁻³.

In this way, the resistivity of the filling portion is reduced, thereby preventing the resistivity of the silicon carbide substrate from increasing due to the formation of the filling portion. Further, because the filling portion is formed after the end surfaces of the SiC substrates are connected to one another, the filling portion does not affect the quality of the SiC substrates even when the filling portion includes many defects. Hence, in order to further reduce the resistivity of the filling portion, in the step of forming the filling portion, a filling portion may be formed which has an impurity concentration exceeding 2×10¹⁹cm⁻³.

The method for manufacturing the silicon carbide substrate may further include the step of smoothing main surfaces of the plurality of SiC substrates after the step of connecting the end surfaces of the plurality of SiC substrates to one another.

Accordingly, when manufacturing semiconductor devices by forming an epitaxial layer made of, for example, silicon carbide on each of the main surfaces of the SiC substrates thus having smoothness, the epitaxial layer can be provided with high crystallinity. The smoothing may be accomplished by, for example, a polishing process.

The method for manufacturing the silicon carbide substrate may further include the step of forming an epitaxial growth layer made of single-crystal silicon carbide on main surfaces of the plurality of SiC substrates having the end surfaces connected to one another.

In this way, a semiconductor substrate can be manufactured which includes an epitaxial growth layer formed on the silicon carbide substrate and serving as a buffer layer or an active layer in a semiconductor device.

In the method for manufacturing the silicon carbide substrate, each of the end surfaces of the SiC substrates prepared in the step of preparing the plurality of SiC substrates may or may not be perpendicular to the main surface of the SiC substrate. More specifically, for example, in the method for manufacturing the silicon carbide substrate, each of the end surfaces of the plurality of SiC substrates prepared in the step of preparing the plurality of SiC substrates may correspond to a cleavage plane.

With each of the end surfaces corresponding to the cleavage plane, damages on a vicinity of the end surface of the SiC substrate can be restrained upon obtaining the SiC substrate. As a result, crystallinity in the vicinity of the end surface of the SiC substrate can be maintained.

In the method for manufacturing the silicon carbide substrate, each of the end surfaces of the plurality of SiC substrates prepared in the step of preparing the plurality of SiC substrates may correspond to a {0001} plane.

With the {0001} plane being a growth plane, an ingot of high-quality single-crystal silicon carbide can be fabricated efficiently. Further, the single-crystal silicon carbide can be cleaved at the {0001} plane. Hence, with each of the end surfaces corresponding to the {0001} plane, high-quality SiC substrates can be prepared efficiently.

In the method for manufacturing the silicon carbide substrate, in the step of connecting the end surfaces of the plurality of SiC substrates to one another, the end surfaces of the plurality of SiC substrates may be connected to one another such that main surfaces of the plurality of SiC substrates are in alignment with one another when viewed in a planar view, each of the main surfaces having an off angle of not less than 50° and not more than 65° relative to a {0001} plane.

By growing single-crystal silicon carbide of hexagonal system in the <0001> direction, a high-quality single-crystal can be fabricated efficiently. From such a silicon carbide single-crystal grown in the <0001> direction, a silicon carbide substrate having a main surface corresponding to the {0001} plane can be obtained efficiently. Meanwhile, by using a silicon carbide substrate having a main surface having an off angle of not less than 50° and not more than 65° relative to the plane orientation of {0001}, a semiconductor device with high performance may be manufactured.

Specifically, for example, it is general that a silicon carbide substrate used in fabricating a MOSFET (Metal Oxide Semiconductor Field Effect Transistor) has a main surface having an off angle of approximately 8° relative to the plane orientation of {0001}. An epitaxial growth layer is formed on this main surface and an oxide film, an electrode, and the like are formed on this epitaxial growth layer, thereby obtaining a MOSFET. In this MOSFET, a channel region is formed in a region including an interface between the epitaxial growth layer and the oxide film. However, in the MOSFET having such a structure, a multiplicity of interface states are formed around the interface between the epitaxial growth layer and the oxide film, i.e., the location in which the channel region is formed, due to the substrate's main surface having an off angle of approximately 8° relative to the {0001} plane. This hinders traveling of carriers, thus decreasing channel mobility.

To address this, in the step of connecting the end surfaces of the SiC substrates to one another, by aligning the main surfaces each having an off angle of not less than 50° and not more than 65° relative to the {0001} plane, the silicon carbide substrate to be manufactured will have a main surface having an off angle of not less than 50° and not more than 65° relative to the {0001} plane. This reduces formation of interface states. Hence, a MOSFET with reduced on-resistance can be fabricated.

In the method for manufacturing the silicon carbide substrate, in the step of connecting the end surfaces of the plurality of SiC substrates to one another, the end surfaces of the plurality of SiC substrates may be connected to one another such that each of the main surfaces of the plurality of SiC substrates, which are in alignment with one another when viewed in a planar view, has an off orientation forming an angle of not more than 5° relative to a <1-100> direction.

The <1-100> direction is a representative off orientation in a silicon carbide substrate. Variation in the off orientation resulting from variation in a slicing process of the process of manufacturing the substrate is adapted to be not more than 5°, which allows an epitaxial growth layer to be formed readily on the silicon carbide substrate.

In the method for manufacturing the silicon carbide substrate, in the step of connecting the end surfaces of the plurality of SiC substrates to one another, the end surfaces of the plurality of SiC substrates may be connected to one another such that each of the main surfaces of the plurality of SiC substrates, which are in alignment with one another when viewed in a planar view, has an off angle of not less than −3° and not more than 5° relative to a {03-38} plane in the <1-100> direction.

Accordingly, channel mobility can be further improved in the case where a MOSFET is fabricated using the silicon carbide substrate. Here, setting the off angle at not less than −3° and not more than +5° relative to the plane orientation of {03-38} is based on a fact that particularly high channel mobility was obtained in this set range as a result of inspecting a relation between the channel mobility and the off angle.

Further, the “off angle relative to the {03-38} plane in the <1-100> direction” refers to an angle formed by an orthogonal projection of a normal line of the above-described main surface to a flat plane defined by the <1-100> direction and the <0001> direction, and a normal line of the {03-38} plane. The sign of positive value corresponds to a case where the orthogonal projection approaches in parallel with the <1-100> direction whereas the sign of negative value corresponds to a case where the orthogonal projection approaches in parallel with the <0001> direction.

It should be noted that the main surface preferably has a plane orientation of substantially {03-38}, and the main surface more preferably has a plane orientation of {03-38}. Here, the expression “the main surface has a plane orientation of substantially {03-38}” is intended to encompass a case where the plane orientation of the main surface of the substrate is included in a range of off angle such that the plane orientation can be substantially regarded as {03-38} in consideration of processing accuracy of the substrate. In this case, the range of off angle is, for example, a range of off angle of ±2° relative to {03-38}. Accordingly, the above-described channel mobility can be further improved.

In the method for manufacturing the silicon carbide substrate, in the step of connecting the end surfaces of the plurality of SiC substrates to one another, the end surfaces of the plurality of SiC substrates may be connected to one another such that each of the main surfaces of the plurality of SiC substrates, which are in alignment with one another when viewed in a planar view, has an off orientation forming an angle of not more than 5° relative to a <11-20>.

The <11-20> direction is a representative off orientation in a silicon carbide substrate, as with the <1-100> direction. Variation in the off orientation resulting from variation in the slicing process of the process of manufacturing the substrate is adapted to be ±5°, which allows an epitaxial growth layer to be formed readily on the SiC substrate.

In the method for manufacturing the silicon carbide substrate, each of the SiC substrates prepared in the step of preparing the plurality of SiC substrates may have a micro pipe density of not more than 1 cm⁻².

Further, in the method for manufacturing the silicon carbide substrate, each of the SiC substrates prepared in the step of preparing the plurality of SiC substrates may have a dislocation density of not more than 1×10⁴ cm⁻².

Further, in the method for manufacturing the silicon carbide substrate, each of the SiC substrates prepared in the step of preparing the plurality of SiC substrates may have a stacking fault density of not more than 0.1 cm⁻¹.

By manufacturing the silicon carbide substrate using the high-quality SiC substrates thus prepared, yield can be improved in fabricating semiconductor devices using the silicon carbide substrate.

In the method for manufacturing the silicon carbide substrate, each of the SiC substrates prepared in the step of preparing the plurality of SiC substrates may have an impurity concentration greater than 5×10¹⁸ cm⁻³ and smaller than 2×10¹⁹ cm⁻³.

When the impurity concentration of each of the SiC substrates is equal to or smaller than 5×10¹⁸ cm⁻³, the resistivity of the SiC substrate becomes too large. On the other hand, when the impurity concentration thereof exceeds 2−10¹⁹ cm⁻³, it is difficult to restrain stacking faults in the SiC substrate. By setting the impurity concentration of the SiC substrate to be larger than 5×10¹⁸ cm⁻³ and smaller than 2×10¹⁹ cm⁻³, stacking faults can be restrained in the SiC substrate while reducing the resistivity thereof.

Here, the term “impurity” in the present application indicates an impurity to be introduced to generate majority carriers in silicon carbide constituting the silicon carbide substrate. In the case where the majority carriers are, for example, electrons, i.e., where the impurity is an n type impurity, an impurity usable therefor is nitrogen, phosphorus, or the like. Phosphorus is capable of further reducing the resistivity of silicon carbide when introduced at the same concentration as that of nitrogen. Accordingly, by employing phosphorus as the impurity, the on-resistance of a semiconductor device can be reduced when fabricating semiconductor devices using the silicon carbide substrate.

In the method for manufacturing the silicon carbide substrate, in the step of connecting the end surfaces of the plurality of SiC substrates to one another, the end surfaces of the plurality of SiC substrates may be connected to one another by heating the plurality of SiC substrates with the end surfaces being in contact with one another.

In this way, in the silicon carbide substrate, a larger area usable for manufacturing of semiconductor devices can be obtained as compared with a case of connecting them with an intermediate layer interposed therebetween.

In the method for manufacturing the silicon carbide substrate, in the step of connecting the end surfaces of the plurality of SiC substrates to one another, the end surfaces may be connected to one another by heating the plurality of SiC substrates under a pressure higher than 10⁻¹ Pa and lower than 10⁴ Pa.

This can accomplish the above-described connection using a simple device, and provide an atmosphere for accomplishing the connection for a relatively short time, thereby reducing manufacturing cost of the silicon carbide substrate.

A silicon carbide substrate according to the present invention includes a plurality of SiC layers each made of single-crystal silicon carbide and arranged side by side when viewed in a planar view, the plurality of SiC layers having end surfaces connected to one another.

In the silicon carbide substrate of the present invention, the end surfaces of the SiC layers are connected to one another such that the plurality of SiC layers each made of single-crystal silicon carbide are arranged side by side when viewed in a planar view. In this way, there can be obtained a silicon carbide substrate which effectively utilizes high-quality SiC substrates (SiC layers) each having a small diameter and obtained from a silicon carbide single-crystal, and which is excellent in crystallinity and can be handled as a silicon carbide substrate having a large diameter.

Thus, according to the silicon carbide substrate in the present invention, a silicon carbide substrate excellent in crystallinity and having a large diameter can be obtained. It should be noted that in order to attain efficient process of manufacturing semiconductor devices using the silicon carbide substrate, the plurality of SiC layers are preferably arranged in the form of a matrix when viewed in a planar view.

In the silicon carbide substrate, each of the SiC layers may have an impurity concentration greater than 5×10¹⁸ cm⁻³ and smaller than 2×10¹⁹ cm⁻³.

When the impurity concentration of each of the SiC layers is equal to or smaller than 5×10¹⁸ cm⁻³, the resistivity of the SiC layer becomes too large. On the other hand, when the impurity concentration thereof exceeds 2×10¹⁹cm⁻³, it is difficult to restrain stacking faults in the SiC layer. By setting the impurity concentration of the SiC layer to be larger than 5×10¹⁸cm⁻³ and smaller than 2×10¹⁹ cm⁻³, stacking faults in the SiC layer can be restrained while reducing the resistivity thereof.

The silicon carbide substrate may further include a filling portion for filling a gap between the plurality of SiC layers.

In this way, when the surface of the silicon carbide substrate is polished, foreign matters such as abrasive particles are restrained from coming into the gap between the SiC layers. It should be noted that the filling portion may be made of, for example, silicon carbide or silicon dioxide.

In the silicon carbide substrate, the filling portion can have an impurity concentration greater than 5×10¹⁸cm⁻³.

In this way, the resistivity of the filling portion is reduced, thereby preventing the resistivity of the silicon carbide substrate from increasing due to the formation of the filling portion. Further, because the filling portion can be formed after connecting the end surfaces of the SiC substrates (SiC layers) to one another, the quality of each of the SiC layers can be avoided from being influenced even when the filling portion has many defects. Hence, for further reduction of the resistivity of the filling portion, the filling portion may have an impurity concentration exceeding 2×10¹⁹ cm⁻³.

The silicon carbide substrate may further include an epitaxial growth layer, which is made of single-crystal silicon carbide and is disposed on main surfaces of the plurality of SiC layers having the end surfaces connected to one another.

In this way, a semiconductor substrate can be provided which includes an epitaxial growth layer formed on the silicon carbide substrate and usable as, for example, a buffer layer or an active layer in a semiconductor device. On this occasion, a SiC layer obtained from a high-quality ingot can be employed for each of the SiC layers. Hence, a high-quality epitaxial growth layer can be formed on the SiC substrates.

Each of the end surfaces of the plurality of SiC layers may or may not be perpendicular to each of the main surfaces of the SiC layers. More specifically, for example, in the silicon carbide substrate, each of the end surfaces of the plurality of SiC layers may correspond to a cleavage plane.

With each of the end surfaces corresponding to the cleavage plane, damages on a vicinity of the end surface of the SiC layer can be restrained upon obtaining the SiC layer (SiC substrate). As a result, crystallinity in the vicinity of the end surface of the SiC layer is maintained.

In the silicon carbide substrate, each of the end surfaces of the plurality of SiC layers may correspond to a {0001} plane.

With the growth plane corresponding to the {0001} plane, an ingot of high-quality single-crystal silicon carbide can be fabricated efficiently. Further, single-crystal silicon carbide can be cleaved at the {0001} plane. Hence, with each of the end surfaces corresponding to the {0001} plane, high-quality SiC layers can be obtained efficiently.

In the silicon carbide substrate, the end surfaces of the plurality of SiC layers may be connected to one another such that main surfaces of the plurality of SiC layers are in alignment with one another when viewed in a planar view, each of the main surfaces having an off angle of not less than 50° and not more than 65° relative to a {0001} plane.

As such, in the silicon carbide substrate of the present invention, each of the main surfaces of the SiC layers is adapted to have an off angle of not less than 50° and not more than 65° relative to the {0001} plane, thereby reducing formation of interface states around an interface between an epitaxial growth layer and an oxide film, i.e., a location where a channel region is formed upon forming a MOSFET using the silicon carbide substrate, for example. Accordingly, a MOSFET with reduced on-resistance can be fabricated.

In the silicon carbide substrate, the end surfaces of the plurality of SiC layers may be connected to one another such that each of the main surfaces of the plurality of SiC layers, which are in alignment with one another when viewed in a planar view, has an off orientation forming an angle of not more than 5° relative to a <1-100> direction.

The <1-100> direction is a representative off orientation in a silicon carbide substrate. Variation in the off orientation resulting from variation in a slicing process of the process of manufacturing the substrate is adapted to be not more than 5°, which allows an epitaxial growth layer to be formed readily on the silicon carbide substrate.

In the silicon carbide substrate, the end surfaces of the plurality of SiC layers may be connected to one another such that each of the main surfaces of the plurality of SiC layers, which are in alignment with one another when viewed in a planar view, has an off angle of not less than −3° and not more than 5° relative to a {03-38} plane in the <1-100> direction.

Accordingly, channel mobility can be further improved in the case where a MOSFET is fabricated using the silicon carbide substrate. Here, the “off angle relative to the {03-38} plane in the <1-100> direction” refers to an angle formed by an orthogonal projection of a normal line of the above-described main surface to a flat plane defined by the <1-100> direction and the <0001> direction, and a normal line of the {03-38} plane. The sign of positive value corresponds to a case where the orthogonal projection approaches in parallel with the <1-100> direction whereas the sign of negative value corresponds to a case where the orthogonal projection approaches in parallel with the <0001> direction.

Further, each of the main surfaces preferably has a plane orientation of substantially {03-38}, and the main surface more preferably has a plane orientation of {03-38}. Here, the expression “the main surface has a plane orientation of substantially {03-38}” is intended to encompass a case where the plane orientation of the main surface of the substrate is included in a range of off angle such that the plane orientation can be substantially regarded as {03-38} in consideration of processing accuracy of the substrate. In this case, the range of off angle is, for example, a range of off angle of ±2° relative to {03-38}. Accordingly, the above-described channel mobility can be further improved.

In the silicon carbide substrate, the end surfaces of the plurality of SiC layers may be connected to one another such that the main surfaces of the plurality of SiC layers, which are in alignment with one another when viewed in a planar view, has an off orientation forming an angle of not more than 5° relative to a <11-20> direction.

The <11-20> direction is a representative off orientation in a silicon carbide substrate, as with the <1-100> direction. Variation in the off orientation resulting from variation in a slicing process of the process of manufacturing the substrate is adapted to be ±5°, which allows an epitaxial growth layer to be formed readily on the silicon carbide substrate.

In the silicon carbide substrate, each of the SiC layers may have a micro pipe density of not more than 1 cm⁻². Further, in the silicon carbide substrate, each of the SiC layers may have a dislocation density of not more than 1×10⁴ cm⁻². Further, in the silicon carbide substrate, each of the SiC layers may have a stacking fault density of not more than 0.1 cm⁻¹.

By employing such high-quality SiC layers, yield can be improved in fabricating semiconductor devices using the silicon carbide substrate.

In the silicon carbide substrate, adjacent ones of the plurality of SiC layers may have end surfaces directly connected to each other.

In this way, a larger area usable for the manufacturing of semiconductor devices can be obtained in the silicon carbide substrate, as compared with a case of connecting them with an intermediate layer interposed therebetween.

### Advantageous Effects of Invention

As apparent from the description above, according to the method for manufacturing the silicon carbide substrate as well as the silicon carbide substrate in the present invention, there can be provided a method for manufacturing a silicon carbide substrate excellent in crystallinity and having a large diameter, as well as such a silicon carbide substrate.

### BRIEF DESCRIPTION OF DRAWINGS

FIG. 1 is a schematic cross sectional view showing a structure of a silicon carbide substrate.

FIG. 2 is a schematic plan view showing the structure of the silicon carbide substrate.

FIG. 3 is a schematic cross sectional view showing the structure of the silicon carbide substrate having an epitaxial layer formed thereon.

FIG. 4 is a flowchart schematically showing a method for manufacturing the silicon carbide substrate.

FIG. 5 is a schematic cross sectional view showing a structure of a silicon carbide substrate in a second embodiment.

FIG. 6 is a flowchart schematically showing a method for manufacturing the silicon carbide substrate in the second embodiment.

FIG. 7 is a schematic cross sectional view for illustrating the method for manufacturing the silicon carbide substrate.

FIG. 8 is a schematic cross sectional view showing a structure of a silicon carbide substrate in a third embodiment.

FIG. 9 is a flowchart schematically showing a method for manufacturing the silicon carbide substrate in the third embodiment.

FIG. 10 is a schematic cross sectional view for illustrating the method for manufacturing the silicon carbide substrate.

FIG. 11 is a schematic cross sectional view showing a structure of a silicon carbide substrate in a fourth embodiment.

FIG. 12 is a flowchart schematically showing a method for manufacturing the silicon carbide substrate in the fourth embodiment.

FIG. 13 is a schematic cross sectional view for illustrating the method for manufacturing the silicon carbide substrate.

FIG. 14 is a schematic cross sectional view showing a structure of a silicon carbide substrate in a fifth embodiment.

FIG. 15 is a flowchart schematically showing a method for manufacturing the silicon carbide substrate in the fifth embodiment.

FIG. 16 is a schematic cross sectional view for illustrating the method for manufacturing the silicon carbide substrate.

FIG. 17 is a schematic cross sectional view showing a structure of a vertical type MOSFET.

FIG. 18 is a flowchart schematically showing a method for manufacturing the vertical type MOSFET.

FIG. 19 is a schematic cross sectional view for illustrating the method for manufacturing the vertical type MOSFET.

FIG. 20 is a schematic cross sectional view for illustrating the method for manufacturing the vertical type MOSFET.

FIG. 21 is a schematic cross sectional view for illustrating the method for manufacturing the vertical type MOSFET.

FIG. 22 is a schematic cross sectional view for illustrating the method for manufacturing the vertical type MOSFET.

### DESCRIPTION OF EMBODIMENTS

The following describes embodiments of the present invention with reference to figures. It should be noted that the same or corresponding portions in the figures are given the same reference characters and are not described repeatedly.

### First Embodiment

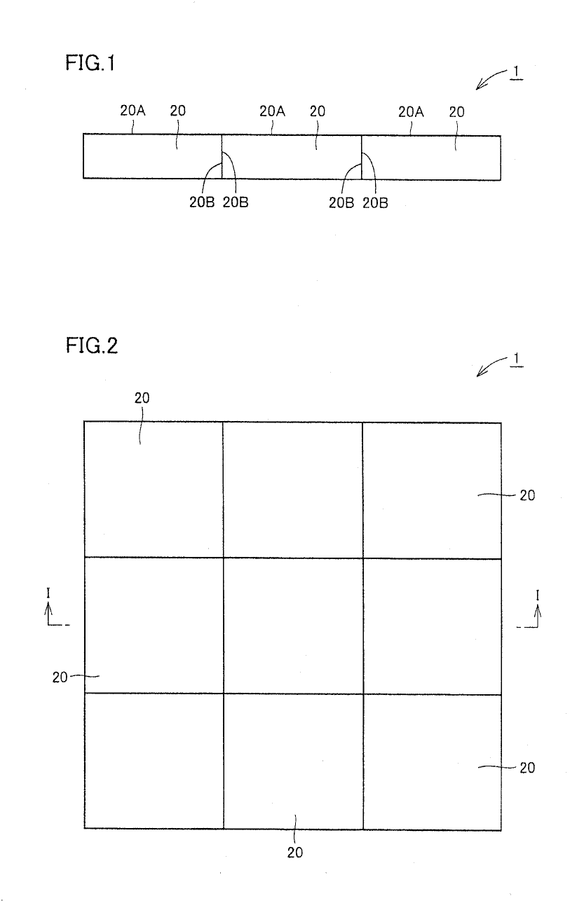

First, one embodiment, i.e., a first embodiment of the present invention will be described with reference to FIG. 1 and FIG. 2. FIG. 1 corresponds to a cross sectional view taken along a line I-I in FIG. 1 Referring to FIG. 1, a silicon carbide substrate 1 of the present embodiment includes a plurality of SiC layers 20 each made of single-crystal silicon carbide and arranged side by side when viewed in a planar view. The plurality of SiC layers 20 have end surfaces 20B connected to one another.

In silicon carbide substrate 1 of the present embodiment, end surfaces 20B of SiC layers 20 are connected to one another such that the plurality of SiC layers 20 each made of single-crystal silicon carbide are arranged side by side when viewed in a planar view. As such, silicon carbide substrate 1 effectively utilizes the SiC substrates (SiC layers) each obtained from a silicon carbide single-crystal having a small diameter and readily achieving high quality, whereby silicon carbide substrate 1 can be handled as a silicon carbide substrate excellent in crystallinity and having a large diameter.

Further, referring to FIG. 1 and FIG. 2, in silicon carbide substrate 1, the plurality of SiC layers 20 are arranged in the form of a matrix when viewed in a planar view. More specifically, adjacent ones of the plurality of SiC layers 20 are disposed such that their end surfaces 20B are in contact with each other. Explaining from a different point of view, end surfaces 20B of the adjacent ones of the plurality of SiC layers 20 are directly connected to each other. Accordingly, silicon carbide substrate 1 is provided with a larger area usable for manufacturing of semiconductor devices, as compared with a case where they are connected to each other with an intermediate layer interposed therebetween. Utilization of silicon carbide substrate 1 having such a large diameter allows for efficient manufacturing process of semiconductor devices. Further, in silicon carbide substrate 1, each of end surfaces 20B of SiC layers 20 is perpendicular to main surface 20A thereof. This allows SiC layers 20 to be readily arranged in the form of a matrix.

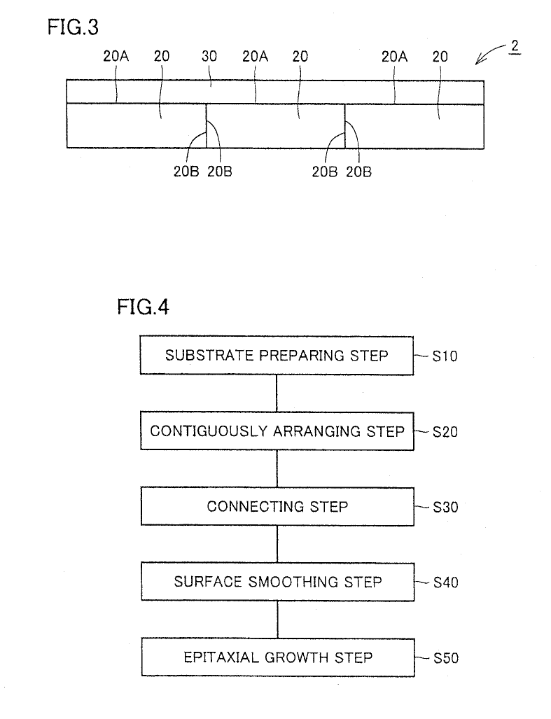

Further, as shown in FIG. 3, an epitaxial growth layer 30 made of single-crystal silicon carbide is formed on main surfaces 20A of SiC layers 20, thereby fabricating a silicon carbide substrate 2 including the epitaxial growth layer, which is usable as a buffer layer or an active layer.

Here, an impurity included in each of SiC layers 20 can be nitrogen or phosphorus. In particular, by adopting phosphorus as the impurity, the resistivity of silicon carbide substrate 1 can become smaller than the resistivity thereof in the case where nitrogen is adopted as the impurity, with their impurity concentrations being the same.

Here, in silicon carbide substrate 1 described above, main surface 20A of each of SiC substrates 20 may have an off angle of not less than 50° and not more than 65° relative to the {0001} plane. By fabricating a MOSFET using such a silicon carbide substrate 1, formation of interface states can be reduced in a channel region, thereby obtaining a MOSFET reduced in on-resistance. Meanwhile, in order to facilitate the manufacturing, main surface 20A of SiC layer 20 may correspond to the {0001} plane.

Further, the off orientation of main surface 20A of SiC layer 20 may form an angle of 5° or less relative to the <1-100> direction. The <1-100> direction is a representative off orientation in a silicon carbide substrate. Variation in the off orientation resulting from variation in a slicing process of the process of manufacturing the substrate is adapted to be 5° or smaller, which allows an epitaxial growth layer to be formed readily on silicon carbide substrate 1.

Further, in silicon carbide substrate 1, main surface 20A of SiC layer 20 preferably has an off angle of not less than −3° and not more than 5° relative to the {03-38} plane in the <1-100> direction. Accordingly, channel mobility can be further improved in the case where a MOSFET is fabricated using silicon carbide substrate 1.

Alternatively, in silicon carbide substrate 1, the off orientation of main surface 20A of SiC layer 20 may form an angle of 5° or smaller relative to the <11 -20> direction.

The <11-20> direction is a representative off orientation in a silicon carbide substrate. Variation in the off orientation resulting from variation in a slicing process of the process of manufacturing the substrate is adapted to be ±5°, which allows an epitaxial growth layer to be formed readily on silicon carbide substrate 1.

Further, it is desirable that SiC layer 20 has an impurity concentration of more than 5×10¹⁸cm⁻³and less than 2×10¹⁹cm⁻³. In this way, the resistivity can be reduced while restraining stacking faults in SiC layer 20.

Further, SiC layer 20 preferably has a micro pipe density of not more than 1 cm⁻². Further, SiC layer 20 preferably has a dislocation density of not more than 1×10⁴cm⁻². Further, SiC layer 20 preferably has a stacking fault density of not more than 0.1 cm⁻¹. By employing such a high-quality SiC layer 20, yield can be improved in fabricating semiconductor devices using silicon carbide substrate 1.

The following describes an exemplary method for manufacturing silicon carbide substrate 1 described above. Referring to FIG. 4, a substrate preparing step is first performed as a step (S10) in the method for manufacturing the silicon carbide substrate in the present embodiment. In this step (S10), referring to FIG. 1 and FIG. 2, the plurality of SiC substrates 20 each of which is made of single-crystal silicon carbide and will be SiC layers 20 are prepared. Each of SiC substrates 20 has the main surface, which will be main surface 20A of SiC layer 20 that will be obtained by this manufacturing method (see FIG. 1). Hence, on this occasion, the plane orientation of the main surface of SiC substrate 20 is selected in accordance with desired plane orientation of main surface 20A. Here, for example, a SiC substrate 20 having a main surface 20A corresponding to the {03-38} plane is prepared. Further, as SiC substrate 20, a substrate is employed which has an impurity concentration of more than 5×10¹⁸ cm⁻³ and less than 2×10¹⁹ cm⁻³.

Next, as a step (S20), a contiguously arranging step is performed. In this step (S20), referring to FIG. 1 and FIG. 2, the plurality of SiC substrates 20 prepared in step (S10) are arranged side by side when viewed in a planar view such that end surfaces 20B of adjacent SiC substrates 20 are in contact with each other.

Next, as a step (S30), a connecting step is performed. In this step (S30), adjacent SiC substrates 20 are connected to each other by heating SiC substrates 20 arranged in step (S20) such that end surfaces 20B of the adjacent ones are in contact with each other. This heating can be performed under reduced pressure (for example, in vacuum). With the above-described process, silicon carbide substrate 1 of the first embodiment is completed.

Further, by performing the following steps to form the epitaxial growth layer on silicon carbide substrate 1, silicon carbide substrate 2 described above may be fabricated. Namely, as a step (S40), a surface smoothing step is performed onto silicon carbide substrate 1 fabricated by performing steps (S10)-(S30). In this step (S40), main surface 20A of each SiC substrate 20 is smoothed by, for example, polishing. This allows a high-quality epitaxial growth layer to be formed on main surface 20A of SiC substrate 20.

Further, as a step (S50), an epitaxial growth step is performed. In this step (S50), referring to FIG. 1 and FIG. 3, epitaxial growth layer 30 is formed on SiC layers 20. In this way, silicon carbide substrate 2 is completed which includes epitaxial growth layer 30 usable as a buffer layer or an active layer in a semiconductor device.

Here, in step (S20), a gap between adjacent SiC substrates 20 is preferably not more than 100 μm. Even when end surfaces 20B of SiC substrates 20 are highly flat, a slight gap is formed between SiC substrates 20. If this gap is more than 100 μm, a state of connection between SiC substrates 20 may not become uniform. By setting the gap between SiC substrates 20 to be not more than 100 μm, SiC substrates 20 can be uniformly connected to each other more securely.

Further, in step (S30), it is preferable to heat SiC substrates 20 to fall within a range of temperature equal to or higher than the sublimation temperature of silicon carbide. This allows SiC substrates 20 to be connected to each other more securely.

Further, heating temperature for SiC substrates 20 in step (S30) is preferably not less than 1800° C. and not more than 2500° C. If the heating temperature is lower than 1800° C., it takes a long time to connect SiC substrates 20 to one another, which results in decreased efficiency in manufacturing silicon carbide substrate 1. On the other hand, if the heating temperature exceeds 2500° C., surfaces of SiC substrates 20 become rough, which may result in generation of a multiplicity of crystal defects in silicon carbide substrate 1 to be fabricated. In order to improve efficiency in manufacturing while restraining generation of defects in silicon carbide substrate 1, the heating temperature for SiC substrates 20 in step (S30) is preferably set at not less than 1900° C. and not more than 2100° C. Further, when the pressure of atmosphere upon the heating in step (S30) is set at not less than 10⁻⁵ Pa and not more than 10⁶ Pa, they can be connected to one another using a simple device. Further, in this step (S30), the plurality of SiC substrates may be heated under a pressure higher than 10⁻¹ Pa and lower than 10⁴ Pa. This can accomplish the above-described connection using a simple device, and provide an atmosphere for accomplishing the connection for a relatively short time, thereby achieving reduced manufacturing cost of silicon carbide substrate 1. Further, the atmosphere upon the heating in step (S30) may be inert gas atmosphere. In the case where the atmosphere is the inert gas atmosphere, the inert gas atmosphere preferably contains at least one selected from a group consisting of argon, helium, and nitrogen. Further, in this step (S30), the plurality of SiC substrates 20 may be heated in an atmosphere obtained by reducing pressure of the atmospheric air. This reduces manufacturing cost of silicon carbide substrate 1.

Further, it has been illustrated in the above-described embodiment that: in step (S10), there are prepared SiC substrates 20 each having main surface 20A corresponding to the {03-38} plane; and in steps (S20) and (S30), they are arranged such that main surfaces 20A each corresponding to the {03-38} plane are in alignment with one another, i.e., main surfaces 20A corresponding to the {03-38} plane are in alignment with one another in one flat plane (in the case where each of main surfaces 20A has an off orientation corresponding to the <1-100> direction). However, instead of this, each of main surfaces 20A may have an off orientation corresponding to, for example, the <11-20> direction.

Further, each of SiC substrates 20 prepared in step (S10) preferably has a micro pipe density of not more than 1 cm⁻². Further, each of SiC substrates 20 prepared in step (S10) preferably has a dislocation density of not more than 1×10⁴ cm⁻². Further, each of SiC substrates 20 prepared in step (S10) preferably has a stacking fault density of not more than 0.1 cm⁻¹. By manufacturing silicon carbide substrate 1 with such high-quality SiC substrates 20 thus prepared, yield can be improved in fabricating semiconductor devices using silicon carbide substrate 1.

Further, each of SiC substrates 20 prepared in step (S10) has an impurity concentration of more than 5×10′¹⁸cm⁻³and less than 2×10¹⁹cm⁻³. This allows for reduced resistivity while restraining stacking faults in each of SiC substrates 20.

### Second Embodiment

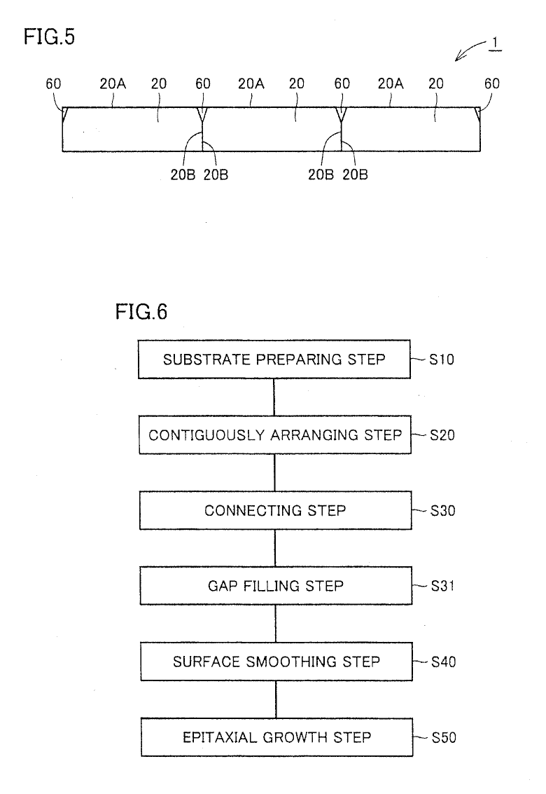

The following describes another embodiment of the present invention, i.e., a second embodiment. Referring to FIG. 5 and FIG. 1, a silicon carbide substrate 1 in the second embodiment has basically the same structure and provides basically the same effects as those of silicon carbide substrate 1 in the first embodiment. However, silicon carbide substrate 1 in the second embodiment is different from that of the first embodiment in that filling portions are provided to fill gaps between SiC layers 20.

Referring to FIG. 5, silicon carbide substrate 2 in the second embodiment further includes filling portions 60 for filling the gaps between the plurality of SiC layers 20. Each of filling portions 60 may be made of, for example, silicon carbide or silicon dioxide. Further, a filling portion 60 made of silicon (Si) or made of a resin may be employed. Filling portion 60 made of Si can be formed by, for example, introducing melted Si into each gap between SiC layers 20. The intermediate layer made of a resin can be formed by, for example, pouring a melted resin into each gap between SiC layers 20 and then performing appropriate hardening treatment to harden the resin. Examples of the resin usable include an acrylic resin, an urethane resin, polypropylene, polystyrene, polyvinyl chloride, a resist, a SiC-containing resin, and the like. Accordingly, silicon carbide substrate 1 in the second embodiment restrains foreign matters such as abrasive particles from entering each gap between SiC layers 20 even when the surface thereof is polished.

It should be noted that each filling portion 60 has an impurity concentration of more than 5×10¹⁸cm⁻³. This achieves reduced resistivity of filling portion 60, thereby preventing the resistivity of silicon carbide substrate 1 from increasing by forming filling portion 60.

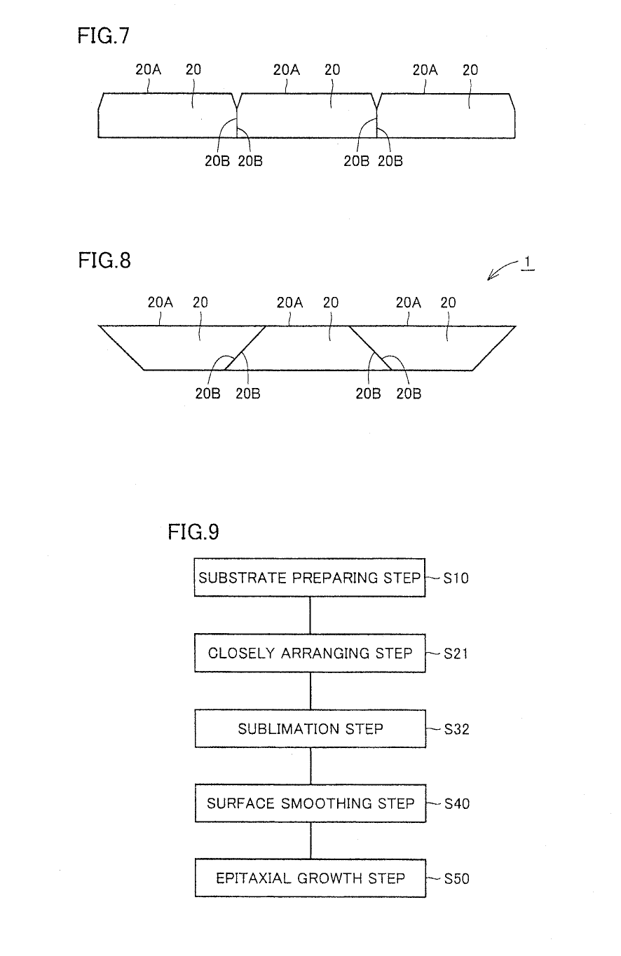

The following describes a method for manufacturing the silicon carbide substrate in the second embodiment. Referring to FIG. 6, in the method for manufacturing the silicon carbide substrate in this embodiment, steps (S10)-(S30) are performed in the same way as in the first embodiment. Accordingly, as shown in FIG. 7, SiC substrates 20 are connected to one another at their end surfaces 20B.

Next, as a step (S31), a gap filling step is performed. In this step (S31), the filling portions are formed to fill the gaps between the plurality of SiC substrates 20 connected to one another. Specifically, referring to FIG. 7 and FIG. 5, for example, a CVD epitaxial method is employed to grow silicon carbide, thereby forming filling portions 60 that fill the gaps between SiC substrates 20. It should be noted that the method for forming filling portions 60 is not limited to the CVD epitaxial method, and the sublimation method or liquid phase epitaxy may be employed, for example. The liquid phase epitaxy can be implemented by, for example, bringing SiC substrates 20 into contact with a Si melt retained in a carbon crucible to supply them with Si from the melt and carbon from the crucible. Further, each of filling portions 60 is not necessarily made of silicon carbide, and may be made of silicon dioxide, for example. A filling portion 60 made of silicon dioxide can be formed by, for example, the CVD method.

Next, as step (S40), the surface smoothing step is performed in the same way as in the first embodiment. On this occasion, filling portions 60 formed on main surfaces 20A of SiC substrates 20 are removed by polishing. Further, filling portions 60 thus formed prevent foreign matters such as abrasive particles from entering the gaps between SiC layers 20. With the above-described procedure, silicon carbide substrate 1 in the second embodiment is completed as shown in FIG. 5. Further, as with the first embodiment, by performing step (S70), a silicon carbide substrate including an epitaxial growth layer can be manufactured.

### Third Embodiment

The following describes still another embodiment of the present invention, i.e., a third embodiment. Referring to FIG. 8 and FIG. 1, a silicon carbide substrate 1 in the third embodiment has basically the same structure and provides basically the same effects as those of silicon carbide substrate 1 in the first embodiment. However, silicon carbide substrate 1 in the third embodiment is different from that of the first embodiment in terms of the shape of each of SiC layers 20.

Referring to FIG. 8, in the third embodiment, end surface 20B of each of SiC layers 20 is not perpendicular to main surface 20A thereof. Further, end surface 20B of SiC layer 20 in the third embodiment corresponds to a cleavage plane. More specifically, in the third embodiment, end surface 20B of SiC layer 20 corresponds to the {0001} plane.

The following describes a method for manufacturing silicon carbide substrate 1 in the third embodiment. Silicon carbide substrate 1 in the third embodiment can be manufactured in basically the same way as in the first embodiment. However, the method for manufacturing the silicon carbide substrate in the third embodiment is different from that in the first embodiment in terms of the shape of each of SiC substrates 20 prepared in step (S10). Accordingly, a different manufacturing method from that in the first embodiment can be employed.

Namely, referring to FIG. 9, in the substrate preparing step performed as step (S10), SiC substrates 20 each corresponding to the shape of each SiC layer 20 in the third embodiment is prepared. Specifically, end surface 20B of each of SiC substrates 20 prepared in step (S10) corresponds to the cleavage plane that is the {0001} plane. This restrains damages on a vicinity of the end surface of SiC substrate 20 when obtaining SiC substrate 20. As a result, crystallinity is maintained in the vicinity of the end surface of SiC substrate 20.

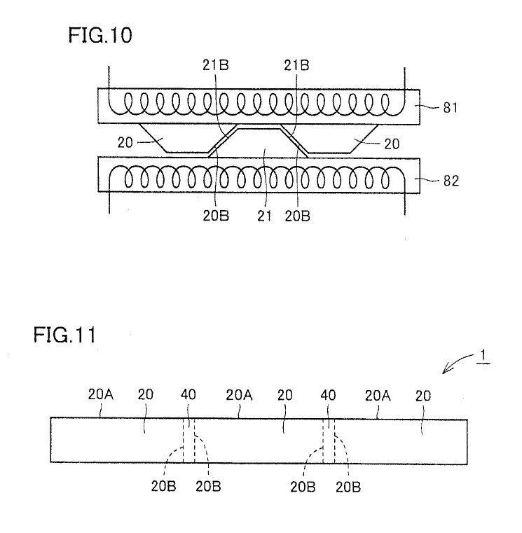

Next, referring to FIG. 9, a closely arranging step is performed as a step (S21). In this step (S21), referring to FIG. 10, adjacent SiC substrates 20 to be SiC layers 20 (see FIG. 8) are held alternately by a first heater 81 and a second heater 82 disposed face to face each other. On this occasion, an appropriate value of a space between a SiC substrate 20 held by first heater 81 and a SiC substrate 20 held by second heater 82 is considered to be associated with a mean free path for a sublimation gas obtained upon heating in a below-described step (S32). Specifically, the average value of the space can be set to be smaller than the mean free path for the sublimation gas obtained upon heating in the below-described step (S32). For example, strictly, a mean free path for atoms and molecules depends on atomic radius and molecule radius at a pressure of 1 Pa and a temperature of 2000° C., but is approximately several cm to several ten cm. Hence, realistically, the space is preferably set at several cm or smaller. More specifically, SiC substrate 20 held by first heater 81 and SiC substrate 20 held by second heater 82 are arranged close to each other such that their end surfaces face each other with a space of not less than 1 μm and not more than 1 cm therebetween. The average value of the space is preferably 1 cm or smaller, more preferably, 1 mm or smaller. Meanwhile, with the average value of the space being 1 μm or greater, there can be secured a sufficient space for sublimation of silicon carbide. It should be noted that this sublimation gas is a gas formed by sublimation of solid silicon carbide, and includes Si, Si₂C, and SiC₂, for example. Further, first heater 81 is disposed at an upper side relative to second heater 82 (upper side in the vertical direction).

Next, as step (S32), a sublimation step is performed. In this step (S32), SiC substrates 20 are heated to a predetermined first temperature by first heater 81. Likewise, SiC substrates 20 are heated to a predetermined second temperature by second heater 82. On this occasion, for example, by thus heating SiC substrates 20 held by second heater 82 to the second temperature, SiC is sublimated from the surfaces of SiC substrates 20 held by second heater 82. The first temperature is set lower than the second temperature. Specifically, for example, the first temperature is set lower than the second temperature by not less than 1° C. and not more than 100° C. The first temperature is preferably 1800° C. or greater and 2500° C. or smaller. Accordingly, SiC in the form of gas as a result of the sublimation from SiC substrates 20 held by second heater 82 reaches the surfaces of SiC substrates 20 held by first heater 81. By maintaining this state, adjacent SiC substrates (SiC layers) 20 are connected to each other at their end surfaces 20B as shown in FIG. 8, thus completing silicon carbide substrate 1 in the third embodiment. Further, as with the first embodiment, by performing steps (S40) and (S50), a silicon carbide substrate including an epitaxial growth layer can be fabricated.

It should be noted that in the manufacturing method in the embodiment described above, SiC substrate 20 held by first heater 81 and SiC substrate 20 held by second heater 82 are arranged in step (S21) with an space therebetween, but they may be arranged without any space therebetween, i.e., arranged in contact with each other. Also in this case, a gap is formed between SiC substrate 20 held by first heater 81 and SiC substrate 20 held by second heater 82. In this gap, SiC is sublimated, thereby obtaining silicon carbide substrate 1 in the third embodiment.

### Fourth Embodiment

The following describes yet another embodiment of the present invention, i.e., a fourth embodiment. Referring to FIG. 11 and FIG. 1, a silicon carbide substrate 1 in the fourth embodiment has basically the same configuration and provides basically the same effects as those of silicon carbide substrate 1 in the first embodiment. However, silicon carbide substrate 1 in the fourth embodiment is different from that of the first embodiment in that amorphous SiC layers each serving as an intermediate layer are provided between adjacent SiC layers.

Namely, referring to FIG. 11, in silicon carbide substrate 1 in the fourth embodiment, each of amorphous SiC layers 40 is provided between adjacent SiC layers 20. Amorphous SiC layer 40 at least has a portion made of amorphous SiC, and serves as an intermediate layer. Then, adjacent SiC layers 20 are connected to each other by this amorphous SiC layer 40. Amorphous SiC layer 40 thus existing facilitates fabrication of silicon carbide substrate 1 in which adjacent SiC layers 20 are connected to each other. Here, a space between adjacent SiC layers 20, i.e., the thickness of the intermediate layer (amorphous SiC layer 40) is preferably set at 100 μm or smaller, more preferably, 10 μm or smaller.

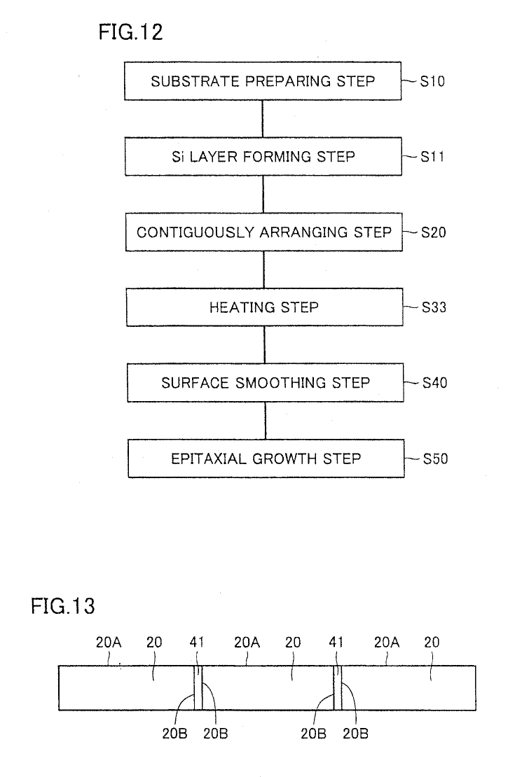

The following describes a method for manufacturing silicon carbide substrate 1 in the fourth embodiment. Referring to FIG. 12, in the method for manufacturing silicon carbide substrate 1 in the fourth embodiment, the substrate preparing step is performed as step (S10) in the same way as in the first embodiment, so as to prepare the plurality of SiC substrates 20.

Next, a Si layer fowling step is performed as a step (S11). In this step (S11), referring to FIG. 13, a Si layer 41 having a thickness of 100 nm is formed on each of end surfaces 20B of SiC substrates 20 prepared in step (S10), for example. This Si layer 41 can be formed using the sputtering method, for example.

Next, as step (S20), the contiguously arranging step is performed. In this step (S20), as with the first embodiment, adjacent SiC substrates 20 are arranged side by side in the form of a matrix such that they come into contact with Si layer 41 formed therebetween in step (S11).

Next, as a step (S33), a heating step is performed. In this step (S33), SiC substrates 20 arranged to come into contact with Si layer 41 formed therebetween is heated, for example, in a mixed gas atmosphere of hydrogen gas and propane gas under a pressure of 1×10³ Pa at approximately 1500° C. for 3 hours. Accordingly, Si layer 41 is supplied with carbon as a result of diffusion mainly from SiC substrates 20, thereby forming amorphous SiC layer 40 as shown in FIG. 11. With the above-described process, silicon carbide substrate 1 in the fourth embodiment can be manufactured. Further, as with the first embodiment, by performing steps (S40) and (S50), a silicon carbide substrate including an epitaxial growth layer may be fabricated.

### Fifth Embodiment

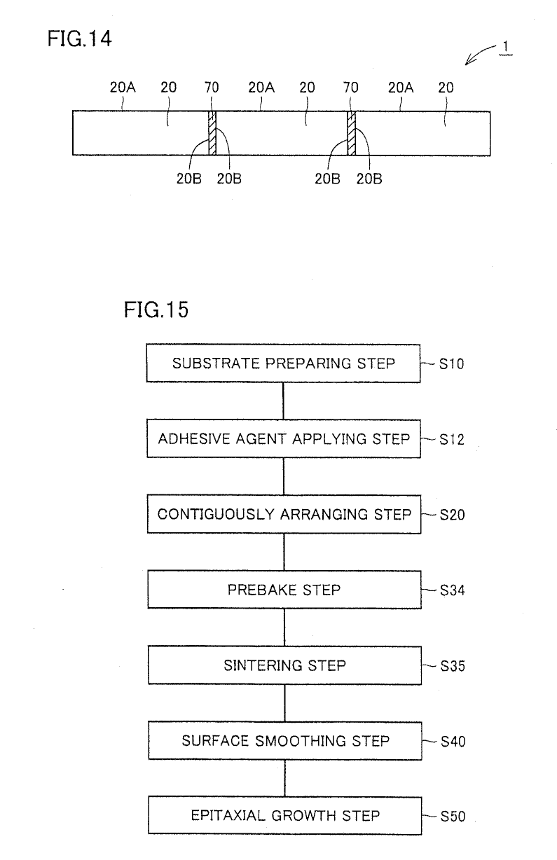

The following describes still another embodiment of the present invention, i.e., a fifth embodiment. Referring to FIG. 14, a silicon carbide substrate 1 in the fifth embodiment has basically the same configuration and provides basically the same effects as those of silicon carbide substrate 1 in the first embodiment. However, silicon carbide substrate 1 in the fifth embodiment is different from that of the first embodiment in that an intermediate layer 70 are formed between adjacent SiC layers 20.

More specifically, intermediate layer 70 includes carbon to serve as a conductor. Here, intermediate layer 70 usable herein includes, for example, graphite particles and non-graphitizable carbon. Preferably, intermediate layer 70 has a carbon composite structure including graphite particles and non-graphitizable carbon.

Namely, in silicon carbide substrate 1 of the fifth embodiment, intermediate layer 70 serving as a conductor by including carbon therein is disposed between adjacent SiC layers 20. Adjacent SiC layers 20 are connected to each other via intermediate layer 70. Intermediate layer 70 thus existing facilitates fabrication of silicon carbide substrate 1 in which adjacent SiC layers 20 are connected to each other at their end surfaces 20B.

The following describes a method for manufacturing silicon carbide substrate 1 in the fifth embodiment. Referring to FIG. 15, in the method for manufacturing silicon carbide substrate 1 in the fifth embodiment, step (S10) is performed in the same way as in the first embodiment.

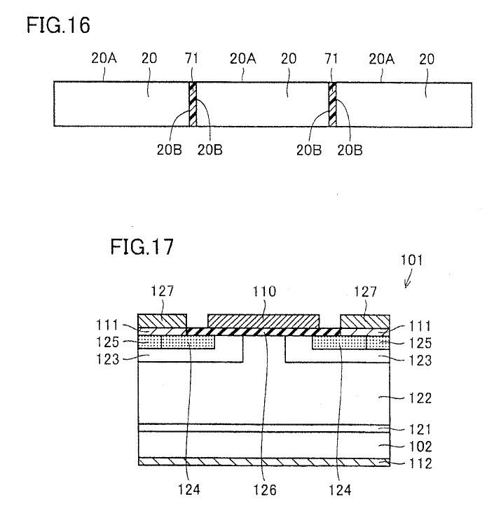

Next, as a step (S12), an adhesive agent applying step is performed. In this step (S12), referring to FIG. 16, for example, a carbon adhesive agent is applied to end surfaces 20B of SiC substrates 20, thereby forming precursor layers 71. The carbon adhesive agent can be formed of, for example, a resin, graphite particles, and a solvent. Here, an exemplary resin usable is a resin formed into non-graphitizable carbon by heating, such as a phenol resin. An exemplary solvent usable is phenol, formaldehyde, ethanol, or the like. Further, the carbon adhesive agent is preferably applied at an amount of not less than 10 mg/cm² and not more than 40 mg/cm², more preferably, at an amount of not less than 20 mg/cm² and not more than 30 mg/cm². Further, the carbon adhesive agent applied preferably has a thickness of not more than 100 μm, more preferably, not more than 50 μm.

Next, as step (S20), the contiguously arranging step is performed. In this step (S20), as with the first embodiment, referring to FIG. 16, adjacent SiC substrates 20 are arranged side by side in the form of a matrix such that they come into contact with precursor layer 71 formed therebetween in step (S12).

Next, as a step (S34), a prebake step is performed. In this step (S34), SiC substrates 20 arranged in contact with precursor layers 71 formed therebetween are heated, thereby removing a solvent component from the carbon adhesive agent constituting each of precursor layers 71. Specifically, SiC substrates 20 are gradually heated to a range of temperature exceeding the boiling point of the solvent component. By performing this heating as long as possible, the adhesive agent is degassed to improve strength in adhesion.

Next, as a step (S35), a sintering step is performed. In this step (S35), SiC substrates 20 with precursor layers 71 heated and accordingly prebaked in step (S34) are heated to a high temperature, preferably, not less than 900° C. and not more than 1100° C., for example, 1000° C. for preferably not less than 10 minutes and not more than 10 hours, for example, for 1 hour, thereby sintering precursor layers 71. Atmosphere employed upon the sintering can be an inert gas atmosphere such as argon. The pressure of the atmosphere can be, for example, atmospheric pressure. In this way, precursor layers 71 are formed into intermediate layers 70 each made of carbon that is a conductor. With the above-described process, silicon carbide substrate 1 in the fifth embodiment can be manufactured. Further, as with the first embodiment, by performing steps (S40) and (S50), a silicon carbide substrate including an epitaxial growth layer may be fabricated.

It should be noted that the fourth and fifth embodiments has illustrated the intermediate layers including amorphous SiC and carbon respectively, but the intermediate layer is not limited to these. Instead of these, an intermediate layer made of a metal can be employed, for example. In this case, as the metal, it is preferable to employ a metal that can make ohmic contact with silicon carbide by forming a silicide, such as nickel.

### Sixth Embodiment

As a sixth embodiment, the following describes one exemplary semiconductor device fabricated using the above-described silicon carbide substrate of the present invention. Referring to FIG. 17, a semiconductor device 101 according to the present invention is a DiMOSFET (Double Implanted MOSFET) of vertical type, and has a substrate 102, a buffer layer 121, a reverse breakdown voltage holding layer 122, p regions 123, n⁺ regions 124, p⁺ regions 125, an oxide film 126, source electrodes 111, upper source electrodes 127, a gate electrode 110, and a drain electrode 112 formed on the backside surface of substrate 102. Specifically, buffer layer 121 made of silicon carbide is formed on the front-side surface of substrate 102 made of silicon carbide of n type conductivity. As substrate 102, there is employed a silicon carbide substrate of the present invention, inclusive of silicon carbide substrates 1 in the first to fifth embodiments. In the case where silicon carbide substrate 1 in each of the first to fifth embodiments is employed, buffer layer 121 is formed on SiC layers 20 of silicon carbide substrate 1. Buffer layer 121 has n type conductivity, and has a thickness of, for example, 0.5 μm. Further, impurity with n type conductivity in buffer layer 121 has a concentration of, for example, 5×10¹⁷ cm⁻³. Formed on buffer layer 121 is reverse breakdown voltage holding layer 122. Reverse breakdown voltage holding layer 122 is made of silicon carbide of n type conductivity, and has a thickness of 10 μm, for example. Further, reverse breakdown voltage holding layer 122 includes an impurity of n type conductivity at a concentration of, for example, 5×10¹⁵ cm⁻³.

Reverse breakdown voltage holding layer 122 has a surface in which p regions 123 of p type conductivity are formed with a space therebetween. In each of p regions 123, an n⁺ region 124 is formed at the surface layer of p region 123. Further, at a location adjacent to n⁺ region 124, a p⁺ region 125 is formed. Oxide film 126 is formed to extend on n⁺ region 124 in one p region 123, p region 123, an exposed portion of reverse breakdown voltage holding layer 122 between the two p regions 123, the other p region 123, and n⁺ region 124 in the other p region 123. On oxide film 126, gate electrode 110 is formed. Further, source electrodes 111 are formed on n⁺ regions 124 and p⁺ regions 125. On source electrodes 111, upper source electrodes 127 are formed. Moreover, drain electrode 112 is formed on the backside surface of substrate 102, i.e., the surface opposite to its front-side surface on which buffer layer 121 is formed.

Semiconductor device 101 in the present embodiment employs, as substrate 102, the silicon carbide substrate in the present invention such as silicon carbide substrate 1 described in each of the first to fifth embodiments. Here, as described above, the silicon carbide substrate of the present invention is a silicon carbide substrate excellent in crystallinity and having a large diameter. Hence, semiconductor device 101 is a semiconductor device in which buffer layer 121 and reverse breakdown voltage holding layer 122 formed on substrate 102 as epitaxial layers are excellent in crystallinity, and is manufactured with reduced cost.

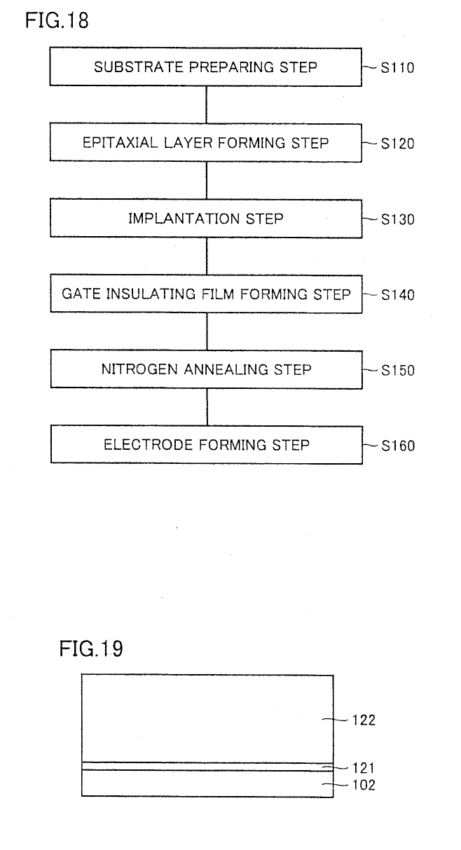

The following describes a method for manufacturing semiconductor device 101 shown in FIG. 17, with reference to FIG. 18-FIG. 22, Referring to FIG. 18, first, a substrate preparing step (S110) is performed. Prepared here is, for example, substrate 102, which is made of silicon carbide and has its main surface corresponding to the (03-38) plane (see FIG. 19). As substrate 102, there is prepared a silicon carbide substrate of the present invention, inclusive of silicon carbide substrate 1 manufactured in accordance with each of the manufacturing methods described in the first to fifth embodiments.

Alternatively, as substrate 102 (see FIG. 19), a substrate may be employed which has n type conductivity and has a substrate resistance of 0.02 Ωcm,

Next, as shown in FIG. 18, an epitaxial layer forming step (S120) is performed. Specifically, buffer layer 121 is formed on the front-side surface of substrate 102. Buffer layer 121 is formed on SiC layers 20 (see FIG. 1, FIG. 5, FIG. 8, FIG. 11, and FIG. 14) of silicon carbide substrate 1 employed as substrate 102. As buffer layer 121, an epitaxial layer is formed which is made of silicon carbide of n type conductivity and has a thickness of 0.5 μm, for example. Buffer layer 121 has a conductive impurity at a concentration of, for example, 5×10¹⁷ cm⁻³. Then, on buffer layer 121, reverse breakdown voltage holding layer 122 is formed as shown in FIG. 19. As reverse breakdown voltage holding layer 122, a layer made of silicon carbide of n type conductivity is fowled using an epitaxial growth method. Reverse breakdown voltage holding layer 122 can have a thickness of, for example, 10 μm. Further, reverse breakdown voltage holding layer 122 includes an impurity of n type conductivity at a concentration of, for example, 5×10¹⁵ cm⁻³.

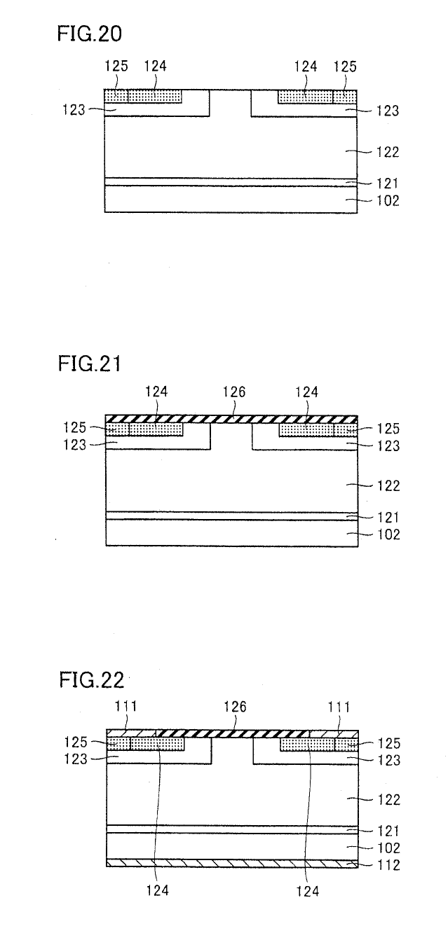

Next, as shown in FIG. 18, an implantation step (S130) is performed. Specifically, an impurity of p type conductivity is implanted into reverse breakdown voltage holding layer 122 using, as a mask, an oxide film formed through photolithography and etching, thereby forming p regions 123 as shown in FIG. 20. Further, after removing the oxide film thus used, an oxide film having a new pattern is formed through photolithography and etching. Using this oxide film as a mask, a conductive impurity of n type conductivity is implanted into predetermined regions to form n⁺ regions 124. In a similar way, a conductive impurity of p type conductivity is implanted to form p regions 125. As a result, the structure shown in FIG. 20 is obtained.

After such an implantation step, an activation annealing process is performed. This activation annealing process can be performed under conditions that, for example, argon gas is employed as atmospheric gas, heating temperature is set at 1700° C., and heating time is set at 30 minutes.

Next, a gate insulating film forming step (S140) is performed as shown in FIG. 18. Specifically, as shown in FIG. 21, oxide film 126 is formed to cover reverse breakdown voltage holding layer 122, p regions 123, n⁺ regions 124, and p⁺ regions 125. As a condition for forming oxide film 126, for example, dry oxidation (thermal oxidation) may be performed. The dry oxidation can be performed under conditions that the heating temperature is set at 1200° C. and the heating time is set at 30 minutes.

Thereafter, a nitrogen annealing step (S150) is performed as shown in FIG. 18. Specifically, an annealing process is performed in atmospheric gas of nitrogen monoxide (NO). Temperature conditions for this annealing process are, for example, as follows: the heating temperature is 1100° C. and the heating time is 120 minutes. As a result, nitrogen atoms are introduced into a vicinity of the interface between oxide film 126 and each of reverse breakdown voltage holding layer 122, p regions 123, n⁺ regions 124, and p⁺ regions 125, which are disposed below oxide film 126. Further, after the annealing step using the atmospheric gas of nitrogen monoxide, additional annealing may be performed using argon (Ar) gas, which is an inert gas. Specifically, using the atmospheric gas of argon gas, the additional annealing may be performed under conditions that the heating temperature is set at 1100° C. and the heating time is set at 60 minutes.

Next, as shown in FIG. 18, an electrode forming step (S160) is performed. Specifically, a resist film having a pattern is formed on oxide film 126 by means of the photolithography method. Using the resist film as a mask, portions of the oxide film above n⁺ regions 124 and p⁺ regions 125 are removed by etching. Thereafter, a conductive film such as a metal is formed on the resist film and formed in openings of oxide film 126 in contact with n⁺ regions 124 and p⁺ regions 125. Thereafter, the resist film is removed, thus removing the conductive film's portions located on the resist film (lift-off). Here, as the conductor, nickel (Ni) can be used, for example. As a result, as shown in FIG. 22, source electrodes 111 and drain electrode 112 can be obtained. It should be noted that on this occasion, heat treatment for alloying is preferably performed. Specifically, using atmospheric gas of argon (Ar) gas, which is an inert gas, the heat treatment (alloying treatment) is performed with the heating temperature being set at 950° C. and the heating time being set at 2 minutes.

Thereafter, on source electrodes 111, upper source electrodes 127 (see FIG. 17) are formed. Further, drain electrode 112 (see FIG. 17) is formed on the backside surface of substrate 102. Further, gate electrode 110 (see FIG. 17) is formed on oxide film 126. In this way, semiconductor device 101 shown in FIG. 17 can be obtained. Namely, semiconductor device 101 is fabricated by forming the epitaxial layers and the electrodes on SiC layers 20 of silicon carbide substrate 1.

It should be noted that in the sixth embodiment, the vertical type MOSFET has been illustrated as one exemplary semiconductor device that can be fabricated using the silicon carbide substrate of the present invention, but the semiconductor device that can be fabricated is not limited to this. For example, various types of semiconductor devices can be fabricated using the silicon carbide substrate of the present invention, such as a JFET (Junction Field Effect Transistor), an IGBT (Insulated Gate Bipolar Transistor), and a Schottky barrier diode. Further, the sixth embodiment has illustrated a case where the semiconductor device is fabricated by forming the epitaxial layer, which serves as an active layer, on the silicon carbide substrate having its main surface corresponding to the (03-38) plane. However, the crystal plane that can be adopted for the main surface is not limited to this and any crystal plane suitable for the purpose of use and including the (0001) plane can be adopted for the main surface.

As described in the sixth embodiment, a semiconductor device can be fabricated using the silicon carbide substrate of the present invention. Specifically, in the semiconductor device of the present invention, on the silicon carbide substrate of the present invention, an epitaxial layer is formed as an active layer. More specifically, the semiconductor device of the present invention includes: the silicon carbide substrate of the present invention; an epitaxial growth layer formed on the silicon carbide substrate; and an electrode formed on the epitaxial layer. In other words, the semiconductor device of the present invention includes: a plurality of SiC layers made of single-crystal silicon carbide and arranged side by side when viewed in a planar view; an epitaxial growth layer formed on the SiC layers; and an electrode formed on the epitaxial layer, the plurality of SiC layers having end surfaces connected to one another.

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### INDUSTRIAL APPLICABILITY

A method for manufacturing a silicon carbide substrate, and the silicon carbide substrate in the present invention are particularly advantageously applicable to a method for manufacturing a silicon carbide substrate required to have both high crystallinity and a large diameter, as well as such a silicon carbide substrate.

### REFERENCE SIGNS LIST

1, 2: silicon carbide substrate; 20: SiC layer (SiC substrate); 20A: main surface; 20B: end surface; 30: epitaxial growth layer; 40: amorphous SiC layer; 41: Si layer; 60: filling portion; 70: intermediate layer; 71: precursor layer; 81: first heater; 82: second heater; 101: semiconductor device; 102: substrate; 110: gate electrode; 111: source electrode; 112: drain electrode; 121: buffer layer; 122: reverse breakdown voltage holding layer; 123: p region; 124: n⁺ region; 125: p⁺ region; 126: oxide film; 127: upper source electrode.

1. A method for manufacturing a silicon carbide substrate, comprising the steps of:
preparing a plurality of SiC substrates each made of single-crystal silicon carbide; and
connecting end surfaces of said plurality of SiC substrates to one another such that said plurality of SiC substrates are arranged side by side when viewed in a planar view.

2. The method for manufacturing the silicon carbide substrate according to claim 1, further comprising the step of forming a filling portion for filling a gap between said plurality of SiC substrates.

3. The method for manufacturing the silicon carbide substrate according to claim 2, wherein in the step of forming said filling portion, said filling portion formed has an impurity concentration greater than 5×10¹⁸ cm⁻³.

4. The method for manufacturing the silicon carbide substrate according to claim 1, further comprising the step of smoothing main surfaces of said plurality of SiC substrates after the step of connecting said end surfaces of said plurality of SiC substrates to one another.

5. The method for manufacturing the silicon carbide substrate according to claim 1, further comprising the step of forming an epitaxial growth layer made of single-crystal silicon carbide on main surfaces of said plurality of SiC substrates having said end surfaces connected to one another.

6. The method for manufacturing the silicon carbide substrate according to claim 1, wherein each of said end surfaces of said plurality of SiC substrates prepared in the step of preparing said plurality of SiC substrates corresponds to a cleavage plane.

7. The method for manufacturing the silicon carbide substrate ROM according to claim 1, wherein each of said end surfaces of said plurality of SiC substrates prepared in the step of preparing said plurality of SiC substrates corresponds to a {0001} plane.

8. The method for manufacturing the silicon carbide substrate according to claim 1, wherein in the step of connecting said end surfaces of said plurality of SiC substrates to one another, said end surfaces of said plurality of SiC substrates are connected to one another such that main surfaces of said plurality of SiC substrates are in alignment with one another when viewed in a planar view, each of said main surfaces having an off angle of not less than 50° and not more than 65° relative to a {0001} plane.

9. The method for manufacturing the silicon carbide substrate according to claim 8, wherein in the step of connecting said end surfaces of said plurality of SiC substrates to one another, said end surfaces of said plurality of SiC substrates are connected to one another such that each of said main surfaces of said plurality of SiC substrates, which are in alignment with one another when viewed in a planar view, has an off orientation forming an angle of not more than 5° relative to a <1-100> direction.

10. The method for manufacturing the silicon carbide substrate according to claim 9, wherein in the step of connecting said end surfaces of said plurality of SiC substrates to one another, said end surfaces of said plurality of SiC substrates are connected to one another such that each of said main surfaces of said plurality of SiC substrates, which are in alignment with one another when viewed in a planar view, has an off angle of not less than −3° and not more than 5° relative to a {03-38} plane in said <1-100> direction.

11. The method for manufacturing the silicon carbide substrate according to claim 1, wherein in the step of connecting said end surfaces of said plurality of SiC substrates to one another, said end surfaces of said plurality of SiC substrates are connected to one another by heating said plurality of SiC substrates with said end surfaces being in contact with one another.

12. The method for manufacturing the silicon carbide substrate according to claim 1, wherein in the step of connecting said end surfaces of said plurality of SiC substrates to one another, said end surfaces are connected to one another by heating said plurality of SiC substrates under a pressure higher than 10⁻¹ Pa and lower than 10⁴ Pa.

13. A silicon carbide substrate comprising a plurality of SiC layers each made of single-crystal silicon carbide and arranged side by side when viewed in a planar view,
said plurality of SiC layers having end surfaces connected to one another.

14. The silicon carbide substrate according to claim 13, further comprising a filling portion for filling a gap between said plurality of SiC layers.

15. The silicon carbide substrate according to claim 13, further comprising an epitaxial growth layer, which is made of single-crystal silicon carbide and is disposed on main surfaces of said plurality of SiC layers having said end surfaces connected to one another.

16. The silicon carbide substrate according to claim 13, wherein each of said end surfaces of said plurality of SiC layers corresponds to a cleavage plane.

17. The silicon carbide substrate according to claim 13, wherein each of said end surfaces of said plurality of SiC layers corresponds to a {0001} plane.

18. The silicon carbide substrate according to claim 13, wherein said end surfaces of said plurality of SiC layers are connected to one another such that main surfaces of said plurality of SiC layers are in alignment with one another when viewed in a planar view, each of said main surfaces having an off angle of not less than 50° and not more than 65° relative to a {0001} plane.

19. The silicon carbide substrate according to claim 18, wherein said end surfaces of said plurality of SiC layers are connected to one another such that each of said main surfaces of said plurality of SiC layers, which are in alignment with one another when viewed in a planar view, has an off orientation forming an angle of not more than 5° relative to a <1-100> direction.

20. The silicon carbide substrate according to claim 19, wherein said end surfaces of said plurality of SiC layers are connected to one another such that each of said main surfaces of said plurality of SiC layers,
